(19) United States
(12) Patent Application Publication
(10) Pub. No.: US 2026/0068073 A1
(43) Pub. Date: Mar. 5, 2026

(54) Support Housing for Receiving Technical Equipment Items

(71) Applicant: ZARGES GmbH, Weilheim (DE)

(72) Inventor: Andreas Veitinger, Seeshaupt (DE)

(21) Appl. No.: 19/301,083

(22) Filed: Aug. 15, 2025

(30) Foreign Application Priority Data
Aug. 27, 2024 (DE) 10 2024 124 460.7

(51) Int. Cl. H05K 7/14

(52) U.S. Cl. CPC H05K 7/1495; H05K 7/1489

(57) ABSTRACT

The present invention relates to a support housing for receiving electronic components, comprising a housing body, in particular according to the 19″ grid dimension according to DIN EN 60297-3-100 or EIA-310-E or according to the half 19″ grid dimension, and at least two oscillating frames mounted independently of one another in the housing body for receiving in each case at least one technical equipment item, wherein at least one oscillating frame is mounted elastically with respect to the housing body.

### CROSS-REFERENCE TO RELATED APPLICATION

This application claims priority to DE Patent Application No. 10 2024 124 460.7, filed Aug. 8, 2024, which is incorporated by reference herein in its entirety.

### BACKGROUND OF THE INVENTION

The present disclosure relates to a support housing for receiving technical equipment items, in particular according to the 19″ grid dimension according to DIN EN 60297-3-100 or EIA-310-E or according to the half 19″ grid dimension. The present invention further relates to a modular system for such a support housing.

### SUMMARY OF THE INVENTION

In the field of technical equipment housings, it is customary for these housings to have standardized dimensions such as the 19″ grid dimension according to DIN EN 60297-3-100 or EIA-310-E or the half 19″ grid dimension. These housings serve for receiving and for protecting technical equipment items such as servers, network devices and network components, IT devices, research instruments, electronic devices such as accumulators and mechanical measuring devices. The equipment housings typically consist of rigid frame structures which securely house the technical equipment items. However, these rigid constructions offer only limited protection against vibrations and shocks which can occur during transport or operation. In particular in environments with high mechanical loads, such as in industrial applications or in mobile applications, vibrations and shocks can lead to damage to the sensitive electronic components. Therefore, so-called oscillating frames which are mounted elastically in the rigid housing are already used for reducing vibrations and shocks.

Despite these measures, the challenge of finding an optimal balance between stability and damping remains. One disadvantage of existing equipment housings is that they offer little to no flexibility with regard to the mounting and vibration damping of the devices contained therein. On the known housings with an oscillating frame, it has proven, inter alia, to be disadvantageous that a compromise must always be found for the one oscillation system with regard to damping for all the components located therein.

CN 217 603 744 U discloses a support housing according to the type, having a plurality of frames which are rigidly connected to the housing and which each mount a server element in an oscillating manner. However, since the frames are rigidly connected to the housing, external forces are transmitted 1:1 into the frames. Also in the case of CN 217 603 744 U, the respective server elements are always mounted in the respective frames via the same mounting technology.

In this respect, there is a need for further improved systems which offer a higher adaptability and a more effective vibration damping in order to ensure optimized accommodation for different loads, requirements and operating conditions.

It is the object of the present invention to overcome the disadvantages from the known prior art, in particular to create a more flexible and/or requirement-optimized support housing.

This object is solved by the features of the independent claims.

Accordingly, a support housing for receiving technical equipment items, such as servers, network devices and network components, IT devices, research instruments, electronic devices such as accumulators and mechanical measuring devices, is provided, which has a housing body, in particular according to the 19″ grid dimension according to DIN EN 60297-3-100 or EIA-310-E or according to the half 19″ grid dimension, and at least two oscillating frames mounted independently of one another in the housing body for receiving in each case at least one technical equipment item. According to the first aspect of the present invention, at least one oscillating frame is mounted elastically with respect to the housing body. Alternatively or additionally, the at least two oscillating frames are mounted differently with respect to the elasticity and/or relative oscillating ability with respect to the housing body.

The housing body can be understood as the outer frame or the outer housing which encloses the oscillating frames and the equipment items contained therein. The oscillating frame can have a rigid structure in order to securely house the equipment items and protect them from damage. The elastic mounting of an oscillating frame means that this oscillating frame is coupled to the housing body by elastic elements such as springs or dampers and/or is decoupled from the housing body as far as possible in terms of vibration technology in order to offer protection against vibrations and shocks.

One advantage of this construction consists, inter alia, in the flexibility when receiving different technical equipment items with varying requirements on the damping and mounting. By the independent mounting of the oscillating frames, different equipment items can be optimally protected and stabilized without compromises having to be made in the damping efficiency. A further advantage is the possibility of removing or replacing individual oscillating frames as required, which facilitates the maintenance and the replacement of equipment items.

According to an exemplary embodiment, the further oscillating frame is mounted in the housing body in such a way that its relative oscillating ability with respect to the housing body as a result of external forces acting on the housing body is lower than that of the other oscillating frame. The relative oscillating ability describes the ability of an oscillating frame to move or oscillate relative to the housing body when external forces, such as vibrations or shocks, act on the housing. The relative oscillating ability depends inter alia on the mounting of the oscillating frames in the housing body. This mounting can be realized by different types of dampers or elastic elements, which can be adapted according to the requirements of the installed devices. The advantage of this configuration lies in the possibility of integrating different technical equipment items which have different requirements on the vibration damping in a single housing body and protecting them against the external forces with in each case one oscillating frame which is individually elastically mounted. One oscillating frame could be provided, for example, for more sensitive devices which require a higher damping, while the other oscillating frame is used for less sensitive or heavier devices which require a lower damping. By the different oscillating ability of the oscillating frames, the support housing can be optimally matched to the specific requirements of the installed equipment items. This leads to an improved protective effect and a higher operational safety of the equipment items, since each equipment item is accommodated in the environment which is optimal for it. In addition, this embodiment permits a more flexible and more efficient use of the available space within the support housing, since various equipment items with different damping requirements can be accommodated together in a support housing.

According to an exemplary embodiment, the at least one further oscillating frame is rigidly connected to the housing body or is mounted elastically with respect to the housing body and/or is mounted in the housing body in a drawer-like removable manner. In particular, the elastically mounted oscillating frame can be mounted in the housing body in particular in a drawer-like removable manner. A rigid connection offers a stable and firm mounting which is particularly suitable for heavy or less sensitive devices. The elastic mounting offers damping and protection against vibrations and shocks, which is advantageous particularly for sensitive electronic devices. The drawer-like removability of the oscillating frame permits simple access to the mounted equipment items and their simple mounting in the housing body. The modular design of the support housing, which is supported by the drawer-like removability of the oscillating frames, also permits a simple adaptation and expansion of the housing in order to meet future requirements. An upgrade of existing support housings is thus also possible.

According to an exemplary embodiment, the elastic mounting comprises at least one buffer made of elastic material, such as rubber in particular with a hardness in the range from 40 to 100 Shore A, a wire cable damper or a functionally equivalent damping element. According to an exemplary development, two buffer or wire cable damper elements are provided at each corner of the oscillating frame. The use of rubber buffers with a specific hardness in the range from 40 to 100 Shore A permits an adaptation of the damping properties to the specific requirements of the installed devices and their sensitivity to vibrations and shocks. Wire cable dampers offer an alternative damping solution which ensures a high energy absorption and a long service life by means of its construction. The arrangement of two buffer or wire cable damper elements at each corner of the oscillating frame ensures a uniform distribution of the damping forces and increases the stability of the oscillating frame within the housing body.

According to an exemplary embodiment, a relative oscillating ability of the at least one elastically mounted oscillating frame with respect to the housing body is adjustable. This oscillating ability can be adjusted by adaptation of the hardness of the elastic mounting or by selective de-/activation of interacting elastic mounting elements. The adaptation of the hardness of the elastic mounting permits the damping properties of the oscillating frame to be modified. The selective de-/activation of interacting elastic mounting elements offers an additional flexibility in that specific mounting elements can be activated or deactivated as required. This permits a precise adaptation of the oscillating ability to the specific requirements of the devices mounted in the oscillating frame. The adjusting of the oscillating ability can be carried out continuously or in a stepwise manner. One advantage is the increased flexibility when receiving different technical equipment items with different requirements on the installation environment. A further advantage is the possibility of optimizing the protective effect of the housing by adapting the damping properties to the specific conditions under which the housing is used.

According to an exemplary embodiment, the elastic mounting comprises at least one elastic buffer which is equipped with an interface, such as a receptacle, and can be connected to a hardener. This connection permits the oscillating ability of the elastic mounting to be adjusted in a stepwise manner. The damping property of the buffer can be adapted by the hardener, which permits a flexible and on-demand adjustment of the oscillating ability. The possibility of adjusting the oscillating ability in a stepwise manner permits a more precise adaptation to the specific requirements of the installed equipment items. The elastic mounting with the elastic buffer and the possibility of connection to a hardener thus offers an improved adaptability and protective function for the technical equipment items accommodated in the support housing.

According to an exemplary embodiment, the elastic mounting is formed by a series connection of at least two in particular identically formed elastic buffer elements and has at least one de-and activatable bridging clamp which is configured to adjust the oscillating ability of the elastic mounting by adding or bridging individual buffer elements. The series connection of the buffer elements permits a finely stepped adaptation of the damping properties. The at least one bridging clamp offers the advantage that the damping properties of the support housing can be adapted flexibly and quickly to the specific requirements of the accommodated technical equipment items. By the possibility of adding or bridging individual buffer elements, the oscillating ability of the housing can be adjusted precisely.

According to an exemplary embodiment, the support housing comprises an adapter piece which is in particular T-shaped in cross section, which is fixedly attached to the housing body and is formed for supporting at least two oscillating frames arranged one above the other in a height unit direction. The adapter piece can be designed such that it stabilizes the oscillating frames which receive technical equipment items and fixes the position thereof in the housing body. The T-shaped configuration in cross section permits an effective distribution of the forces which arise as a result of the oscillations and movements of the accommodated devices and thus contributes to the stability and longevity of the entire system. One advantage of this construction lies in the improved modularity and flexibility of the support housing.

According to a further aspect of the present invention, which can be combined with the preceding aspects and exemplary embodiments, a support housing for receiving technical equipment items is provided, which has a housing body, in particular according to the 19″ grid dimension according to DIN EN 60297-3-100 or EIA-310-E or according to the half 19″ grid dimension, at least one oscillating frame for receiving in each case at least one technical equipment item and a mounting for in particular elastically supporting the oscillating frame on the housing body.

According to the further aspect according to the invention, the mounting is configured adjustably in such a way that the relative oscillating ability of the oscillating frame with respect to the housing body is in particular continuously adjustable. The in particular continuous adjustability of the oscillating ability offers the advantage that the damping properties of the oscillating frame can be adapted precisely to the specific requirements of the installed equipment items. This is particularly advantageous when devices with different sensitivities to vibrations and shocks have to be accommodated in a housing. By the possibility of adjusting the oscillating ability individually, the protection of the equipment items can be optimized and their service life can be extended. In addition, this flexibility permits a simpler adaptation of the support housing to different application scenarios, whether in stationary operation or during transport. A further advantage of the continuous adjustability is the improvement of the user friendliness, since adaptations can be carried out without great effort.

According to an exemplary embodiment, the support housing comprises a sensor system which is configured to detect the weight and/or an acceleration acting on the support housing and/or a vibration acting on the support housing, and a controller which is configured to adjust the relative oscillating ability depending on the sensor system, in particular depending on data detected by the sensor system. The sensor system can measure physical variables such as weight, acceleration and vibrations. The controller can process the data detected by the sensor system and then make adaptations to the mounting. These adaptations relate to the relative oscillating ability, which means that the damping properties of the oscillating frames can be changed in real time in order to ensure optimal conditions for the devices located in the housing. One advantage is the improved adaptability of the housing to different operating conditions. By the continuous monitoring and adaptation, the oscillating frames can be adjusted such that they offer optimal damping properties, irrespective of whether the housing is exposed to strong vibrations, sudden accelerations or varying weights. In addition, the sensor system permits a precise diagnosis and monitoring of the state of the support housing and of the equipment items contained therein, which facilitates the maintenance and fault detection. The ability to adapt the oscillating ability in real time ensures that the housing always operates under optimal conditions, which is of great importance in particular in demanding environments such as military or medical technology.

According to an exemplary embodiment, the support housing comprises a database on which empirical values for the weight and/or an acceleration acting on the support housing and/or a vibration acting on the support housing are stored, and a controller which is configured to adjust the relative oscillating ability depending on the empirical values of the database. The term “database” relates to a system for storing and managing data which contain specific information about the physical loads and properties of the technical equipment items accommodated in the support housing. This database stores empirical values which originate from previous measurements or simulations and comprise information about the weight of the devices and the forces acting on the housing, such as accelerations and vibrations. The controller can change, for example, the damping properties of the oscillating frames in order to optimize the oscillating ability in real time. The oscillating frames can be adjusted dynamically and precisely by the storage and use of empirical values.

According to a further aspect of the present invention, which can be combined with the preceding aspects and exemplary embodiments, a modular system for a support housing formed in particular according to one of the previously described aspects and/or exemplary embodiments for receiving technical equipment items is provided.

The modular system comprises a plurality of housing bodies which differ with respect to their width according to the 19″ grid dimension according to DIN EN 60297-3-100 or EIA-310-E or according to the half 19″ grid dimension, a height unit dimension and/or a nominal depth. These housing bodies thus offer flexibility in the adaptation to different spatial requirements and permit an optimized use of space. Furthermore, the system comprises a plurality of oscillating frames which are in each case adapted to the overall dimensions of a housing body and serve for receiving at least one technical equipment device. These oscillating frames are designed such that they can meet different requirements on the mounting and the protection of the installed devices by being equipped, for example, with different damping properties. This enables a requirement-optimized mounting of the devices, as a result of which the oscillating frames can be individually matched to the specific requirements of the installed components. In addition, the system comprises a plurality of mountings which serve for supporting the oscillating frames in the housing body. These mountings differ with respect to their relative elastic oscillating ability of the oscillating frame with respect to the housing body, their fastening interfaces for connecting to the housing body and/or the oscillating frame, and their installation space requirement. This variety of mountings permits the oscillating frames to be mounted flexibly and as required, which leads to an improved vibration and shock damping and thus increases the protection of the technical equipment items. In order to form a support housing, a housing body is combined with at least one oscillating frame and at least one mounting, which permits a modular and flexible adaptation to different technical requirements and application scenarios.

According to an exemplary embodiment, a plurality of pre-assembly units is provided by in each case one oscillating frame and one mounting being pre-assembled. In this context, the term modular system relates to a modular kit which consists of a plurality of prefabricated units which can be combined and adapted flexibly in order to meet specific requirements. The preassembly of these units means that in each case one oscillating frame with the associated mountings is already assembled before the final mounting in the housing body. On the one hand, the assembly process is simplified and accelerated overall, since fewer work steps are required on site. On the other hand, the quality and consistency of the mounting is improved, since the preassembly can be carried out under controlled conditions. This reduces the risk of assembly errors and ensures that the oscillating frames and mountings are optimally matched to one another. A further advantage of the modular system with pre-assembled units is the increased flexibility in the configuration of the housing. Since the oscillating frames and mountings are already pre-assembled, they can be easily replaced or rearranged depending on the specific requirements of the technical equipment items to be installed.

Preferred embodiments are given in the dependent claims.

### BRIEF DESCRIPTION OF THE DRAWINGS

Further properties, features and advantages of the invention will become clear by means of a description of preferred embodiments of the invention with reference to the accompanying exemplary drawings, in which:

FIG. 1 shows a schematic front view of an exemplary embodiment of a support housing according to the invention with two oscillating frames;

FIG. 2 shows a schematic lateral front view of an exemplary embodiment of a support housing according to the invention with two oscillating frames;

FIG. 3 shows a schematic lateral front view of an exemplary embodiment of a support housing according to the invention with three oscillating frames;

FIG. 4 shows a schematic lateral front view of an exemplary embodiment of an oscillating frame with eight buffers;

FIG. 5 shows a schematic lateral front view of a further exemplary embodiment of an oscillating frame with 16 buffers;

FIG. 6 shows a schematic detail view of an exemplary embodiment of the interface between housing body and oscillating frame by means of a bearing element;

FIG. 7 shows a schematic detail view of an exemplary embodiment of the adapter piece;

FIG. 8 shows a schematic detail view of an exemplary embodiment of the locking mechanism of a removable oscillating frame;

FIG. 9 shows a schematic detail view of an exemplary embodiment of the interface between housing body and oscillating frame by means of an adjustable buffer element;

FIG. 10a shows a schematic detail view of a further exemplary embodiment of the interface between housing body and oscillating frame by means of a further adjustable buffer element in a first operating state;

FIG. 10b shows a schematic detail view of a further exemplary embodiment of the interface between housing body and oscillating frame by means of a further adjustable buffer element in a second operating state;

FIG. 11a shows a schematic illustration of an exemplary embodiment of a series connection of buffers in a first operating state;

FIG. 11b shows a schematic illustration of an exemplary embodiment of a series connection of buffers in a second operating state; and

FIG. 12 shows a schematic illustration of a further exemplary embodiment of a series connection of buffers.

### DETAILED DESCRIPTION

In the following description of exemplary embodiments, a support housing according to the invention is generally provided with the reference number 1. Identical or similar components are provided with identical or similar reference numbers.

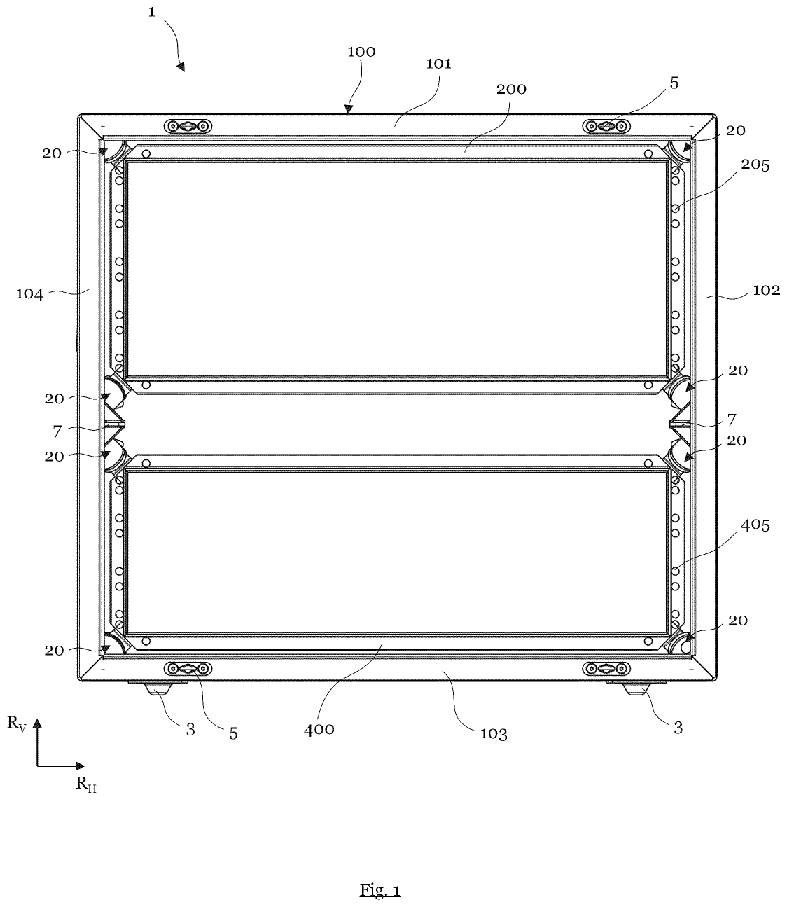

FIG. 1 shows a front view of an opened support housing 1. In general, the support housing comprises a housing body 100 which comprises in particular four wall elements 101, 102, 103, 104, and also two closure covers 15 which are not illustrated and which can in each case be detachably attached to the front side and rear side of the housing body 100. The housing body 100 shown in FIG. 1 has four wall elements 101 to 104 connected to one another at right angles, but an embodiment of a single element is also conceivable. In this case, the wall element 101 forms the upper side, the wall element 103 forms the lower side and the wall elements 102 and 104 in each case form a side wall of the housing body 100. The walls 101 to 104 are connected to one another in such a way that they form a body which is open toward a front side and rear side and in which the oscillating frames 200 and 400 are arranged. Stand feet 3 which ensure a secure stand of the entire support housing 1 are attached to the lower side of the housing body 100, that is to say of the wall element 103.

The wall elements 101 and 103 of the housing body have in each case two closure recesses 5 on the front side and analogously on the rear side of the housing body 100 on their end faces. These serve in each case for fastening a closure cover (not illustrated) on the front side and rear side to the housing body 100 by means of a rotary closure and for closing said housing body as a result.

In the embodiments shown in FIGS. 1 to 3, the wall elements 101, 102, 103, 104 and also the closure covers 15 are produced from metal, in particular from aluminum. Aluminum is particularly advantageous since it has both a high stability to mechanical influences such as impacts or shocks, is corrosion-resistant and lightweight. In addition, aluminum also offers protection against electromagnetic influences such as electromagnetic radiation. It is conceivable for the housing body 100 to be produced from a different metal, such as, for example, stainless steel or from other materials such as GRP, CFRP, plastic or wood.

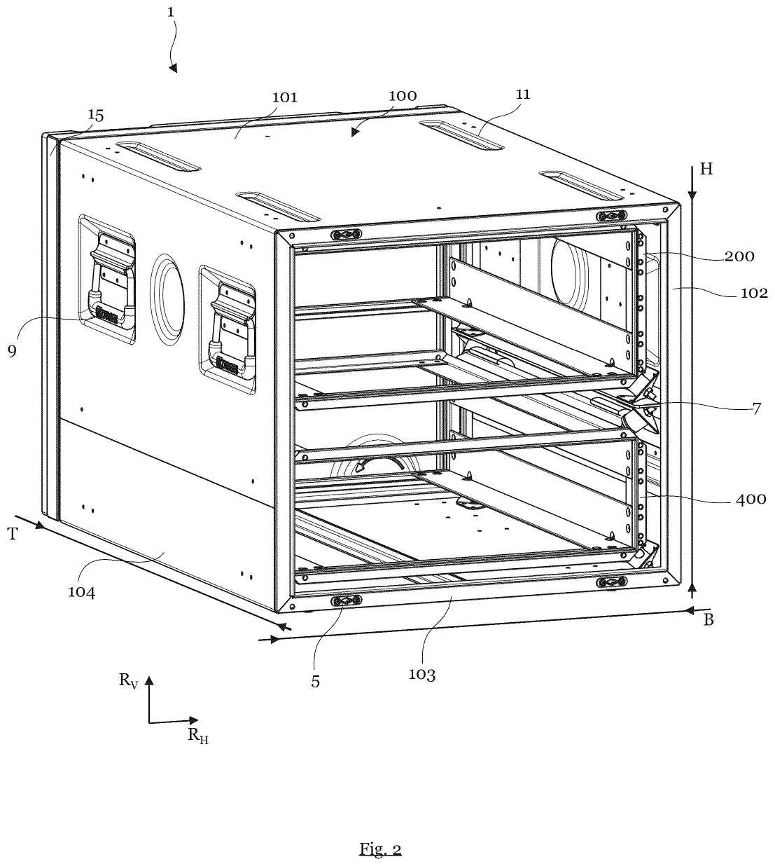

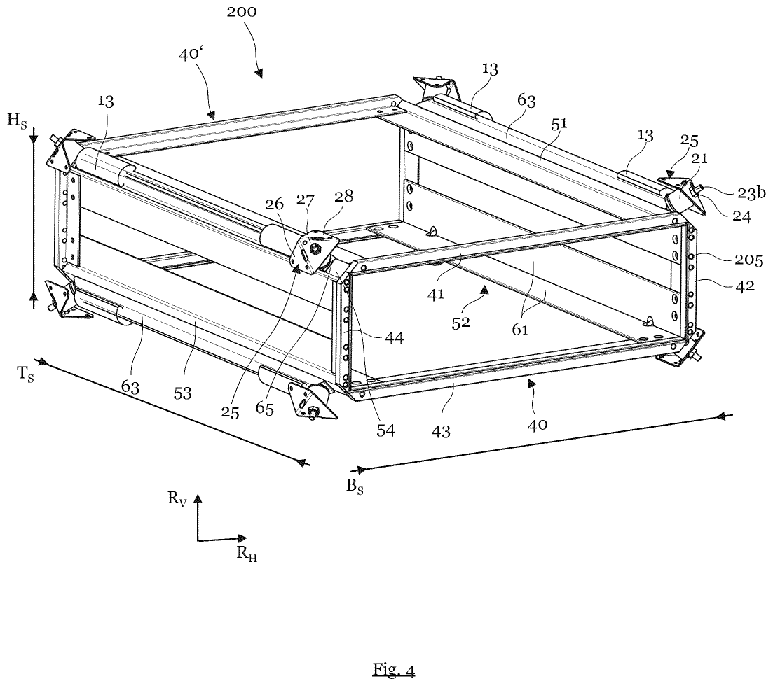

Two oscillating frames 200 and 400 are arranged within the housing body. The structure of the oscillating frames 200, 400 is shown in more detail in FIG. 4. Oscillating frame 200 forms the upper oscillating frame and oscillating frame 400 forms the lower oscillating frame in the housing body 100. The two oscillating frames 200 and 400 each have a width B_{S} corresponding to the 19″ pitch, the half 19″ pitch, in order to be able to receive technical equipment items (not shown here). For fastening the technical equipment items to or in the oscillating frames 200, 400, the latter have corresponding fastening holes 205, 405. The dimensioning of the housing body 100 is such that the oscillating frames 200, 400 are at a distance from the housing body 1 in each direction, with the result that the oscillating frames 200, 400 have sufficient oscillating play when vibrations, impacts or shocks occur in order not to strike against the housing body. In order to avoid damage to the technical equipment components in the event of overloading of the mounting elements 20 described below, additional stop dampers 13, which are illustrated in FIG. 2, are attached to the oscillating frame.

The oscillating frames 200, 400 are connected to the housing body 100 via bearing elements 20. The bearing elements 20 are fastened to the oscillating frames 200, 400 and, according to the embodiment illustrated by way of example, are inclined at an angle of 45 degrees with respect to the horizontal direction R_{H} or vertical direction R_{V} of the support housing 1, wherein it is clear that the angle can be adapted depending on the damper and/or support housing. The mounting elements 20 are described in more detail with reference to FIG. 4.

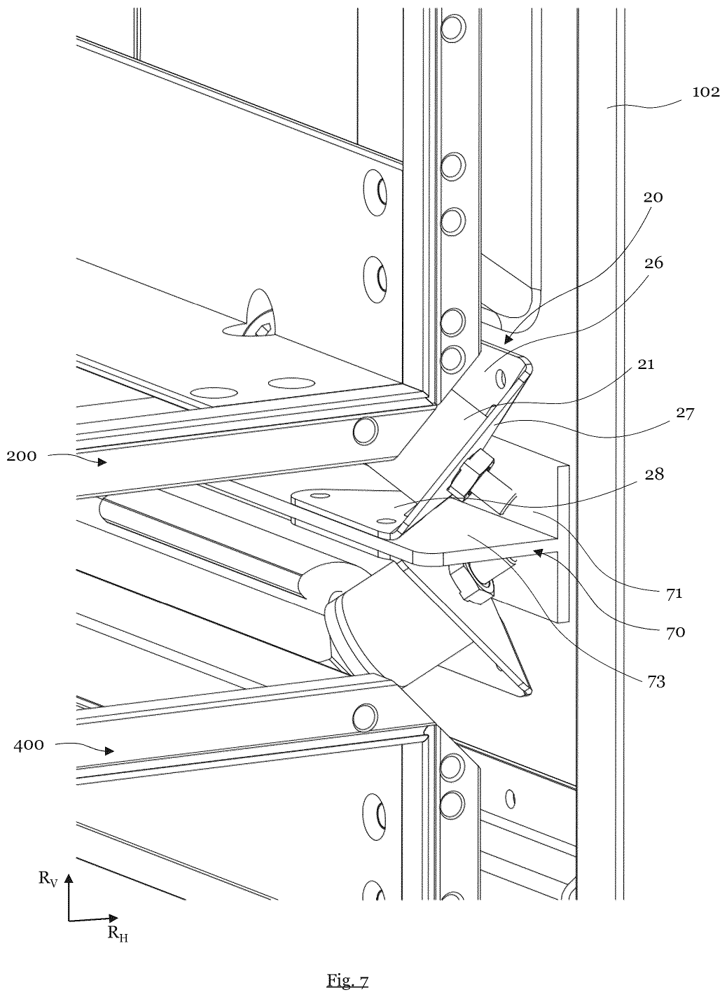

In the vertical direction R_{V}, the lower bearing elements 20 of the upper oscillating frame 200 and the upper bearing elements 20 of the lower oscillating frame 400 are connected to the wall elements 102 and 104 of the housing body 100 via an adapter piece 70. According to the exemplary embodiment, the adapter piece 70 is T-shaped in cross section, wherein other shapes are also conceivable, and is arranged in such a way that a first section 71 is oriented parallel to the side walls 102, 104 of the housing body 100 and is fixedly connected thereto, and the second section 73 perpendicular thereto projects into the interior of the housing body 100 and forms a horizontal surface. The adapter piece 70 is illustrated in detail in FIG. 7.

The two oscillating frames 200, 400 are mounted oscillatingly independently of one another. This means that they are mounted and damped independently of one another on the housing body 100 and exert no influence on one another. There is also the possibility of only one of the oscillating frames 200, 400 being mounted in a damped manner, that is to say in an oscillating manner, and the corresponding other oscillating frame having a rigid connection to the housing body 100; this configuration is not illustrated in the figures.

With reference to FIG. 2, a lateral front view of the support housing illustrated in FIG. 1 is shown. It can be seen in FIG. 2 that the support housing 1 has a nominal width B, a nominal depth T and also a nominal height H. The nominal height H extends along the vertical direction R_{V}, nominal width B and nominal depth T along the horizontal direction R_{H} of the support housing 1. The opening of the housing body 100 is defined by the nominal width B and nominal height H, minus the thickness of the wall elements 102 and 104 and also 101 and 103.

The side wall elements 102 and 104 have in each case two carrying handles 9 on their outer side, which carrying handles ensure a simplified transport of the support housing 1. The upper wall element 101 is provided on its outer side with four countersinkings 11 which can receive the stand feet 3 of a further support housing in order to enable a secure stacking of support housings 1.

A closure cover 15 is attached to the rear side of the support housing 1 illustrated in FIG. 2.

The two T-shaped adapter pieces 70 extend in FIG. 2 over the entire nominal depth T of the housing body 100, but it is also conceivable for the adapter pieces 70 to be of two-part design, with the result that each of these pieces extends over less than 50% of the nominal depth T of the housing body 100, with the result that four adapter pieces 70 would be used in the exemplary embodiment shown in FIG. 2.

FIG. 2 shows an embodiment of the support housing 1 with two elastically mounted oscillating frames 200, 400 of different heights. It goes without saying that the mounting elements 20 of the two oscillating frames 200, 400 do not have to have the same elastic properties. It is conceivable for one oscillating frame to be mounted with mounting elements of greater elasticity than the other, depending on the desired oscillation damping properties for the respective oscillating frames 200, 400.

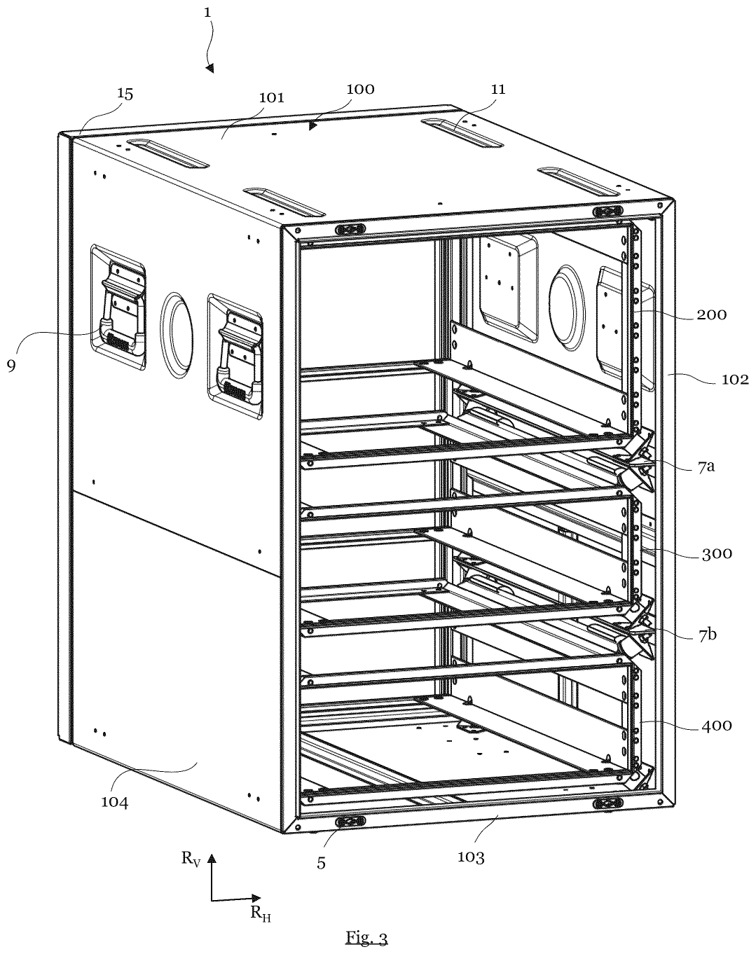

FIG. 3 illustrates a further embodiment of a support housing 1 with three oscillating frames 200, 300, 400. The upper oscillating frame 200 and the middle oscillating frame 300 are connected to the wall elements 102 and 104 via a common adapter piece pair 70a, and the middle oscillating frame 300 and the lower oscillating frame 400 are connected via a common adapter piece pair 70b.

FIG. 4 shows the detailed structure of an oscillating frame 200 including bearing elements 20. The oscillating frame 200 has, in principle, 12 profile bars, wherein in each case four profile bars 41, 42, 43, 44 form two rectangular end sides 40, 40′ of the oscillating frame 200. The end sides 40, 40′ serve as mounting openings into which the technical equipment items to be received are pushed into the oscillating frame 200 and placed. The profile rods 41, 42, 43, 44 have fastening holes 205 which serve for connecting the technical equipment items to be received to the oscillating frame 200. The length of the profile rods 42 and 44 defines the height H_{S} of the oscillating frame 200, the profile rods 41 and 43 define the width B_{S} of the oscillating frame 200. Since primarily electrical components such as servers are intended to be installed in the oscillating frame 200, the oscillating frame 200 usually has a width corresponding to the 19″ grid dimension or the half 19″ grid dimension, but is not restricted thereto.

In the case of the 19″ pitch, the width B_{S}, measured from the inner edge of the profile rod 44 to the inner edge of the profile rod 42, is 450 mm and the center points of the fastening holes 205, which are arranged in each case between the two profile rods 44 and 42 at the same position in the vertical direction R_{V}, are spaced apart from one another by 465 mm.

In the case of the half 19″ pitch, the width B_{S}, measured from the inner edge of the profile rod 44 to the inner edge of the profile rod 42, is 237 mm and the center points of the fastening holes 205, which are arranged in each case between the two profile rods 44 and 42 at the same position in the vertical direction R_{V}, are spaced apart from one another by 251.5 mm.

The end sides 40, 40′ have a rectangular contour in cross section, but the four corners of the latter are beveled at an angle of 45 degrees on the outer side. This results in a rectangular inner contour and an octagonal outer contour of the end sides 40, 40′.

The profile rods 51, 52, 53, 54 connect the two end sides 40, 40′ at the corners thereof to form a cuboid-shaped oscillating frame 200. The depth T_{S} of the oscillating frame 200 is thus defined by the length of the profile rods 51, 52, 53, 54. The profile rods 51, 52, 53, 54 connecting the end sides 40, 40′ have a corresponding bevel corresponding to the beveled corners of the outer contour of the end sides 40, 40′, such that the profile rods 51, 52, 53, 54, in a plan view frontally onto one of the end sides 40, 40′ of the oscillating frame 200, do not protrude beyond the contour of the latter (see FIG. 1).

In order to increase the stability along the depth of the oscillating frame 200, a total of eight stiffening elements 61 are attached parallel to the profile rods 51, 52, 53, 54 to the profiles 41, 42, 43, 44 forming the end sides 40, 40′. In this case, in each case two stiffening elements 61 are connected to the profiles 41, 42, 43 and 44 abuttingly at each corner of the end sides 40, 40′. The stiffening elements 61 have a greater width than thickness and thus also serve as supporting surfaces for the technical equipment items to be received in the oscillating frame 200 both in the vertical direction R_{V} and in the horizontal direction R_{H}.

A further profile rod 63 is connected on each of the profile rods 51, 52, 53, 54 in each case on the beveled surface thereof pointing outwards from the oscillating frame 200. Two stop dampers 13 are attached to each of these profile rods 63. The profile bars 63 have a smaller longitudinal extent than the profile bars 51, 52, 53, 54 and have at their end a bearing mounting surface 65 beveled by 45 degrees. In each case one bearing element 20 is fastened to this bearing mounting surface 65. Overall, the oscillating frame 200 is mounted in the housing body 100 by means of eight bearing elements 20. As a result of the beveled bearing mounting surfaces 65 of the profile bars 63 in combination with the outwardly beveled profile bars 51, 52, 53, 54, each of the bearing elements 20 is inclined by 45 degrees with respect to all three spatial axes. Accordingly, each of the bearing elements 20 can absorb forces in any spatial direction. This has the advantage that the technical equipment items mounted in the oscillating frame 200 are protected against vibrations, shocks and shocks of all types and directions.

The stop dampers 13 have a semicylindrical shape and preferably consist of an elastic material such as rubber. They are attached to the profile rods 63 such that they come into contact with the wall elements 101, 102, 103 or 104 of the housing body and generate additional damping in the event of vibration of the support housing which cannot be absorbed or damped sufficiently by the mounting elements 20.

Preferably, all the abovementioned profile bars (41, 42, 43, 44, 51, 52, 53, 54, 63) and also the stiffening elements 61 are produced from aluminum in order to form an oscillating frame 200 which is as stable as possible and at the same time lightweight, in order that the mounting elements 20 are loaded as slightly as possible by the inherent weight of the oscillating frame 200. However, production from plastic, other metals or materials is also conceivable.

The bearing elements 20 shown in FIG. 4 each comprise two elements, a buffer element 21, and a housing connecting element 25. The buffer element 21 is a cylindrical rubber buffer, on the end faces of which threaded pins 23a, 23b are attached; threaded bores or other fastening means are alternatively provided. One of the two threaded pins 23a is screwed to the bearing mounting surface 65 of the oscillating frame 200, and the opposite threaded pin 23b is attached to the housing connecting element 25 by means of a nut 24. The threaded pin 23a is concealed in the figures. The housing connecting element 25 is a rectangular flat part which is bent in such a way that three triangular surfaces 26, 27, 28 which are angled with respect to one another are formed. A flat part is to be understood as meaning an element whose length and width are many times greater than its thickness. The surfaces are angled in such a way that the two outer surfaces 26 and 28 are angled in each case by 135 degrees with respect to the central surface 27, with the result that the surfaces 26 and 28 lie perpendicularly with respect to one another. The buffer element 21 is attached to the central surface 27 via the threaded pin 23b and a nut 24 and stands perpendicularly thereon. This makes it possible that, in the installed state of the oscillating frame 200 in the housing body 100, the surface 26 of the housing connecting element 25 lies parallel to one of the side wall elements 102, 104 and the surface 28 of the same housing connecting element 25 lies parallel either to the upper or lower wall element 101, 103 or parallel to the horizontal second section 73 of the T-shaped adapter piece 70, while the buffer element 21 is inclined by 45 degrees with respect to all spatial axes.

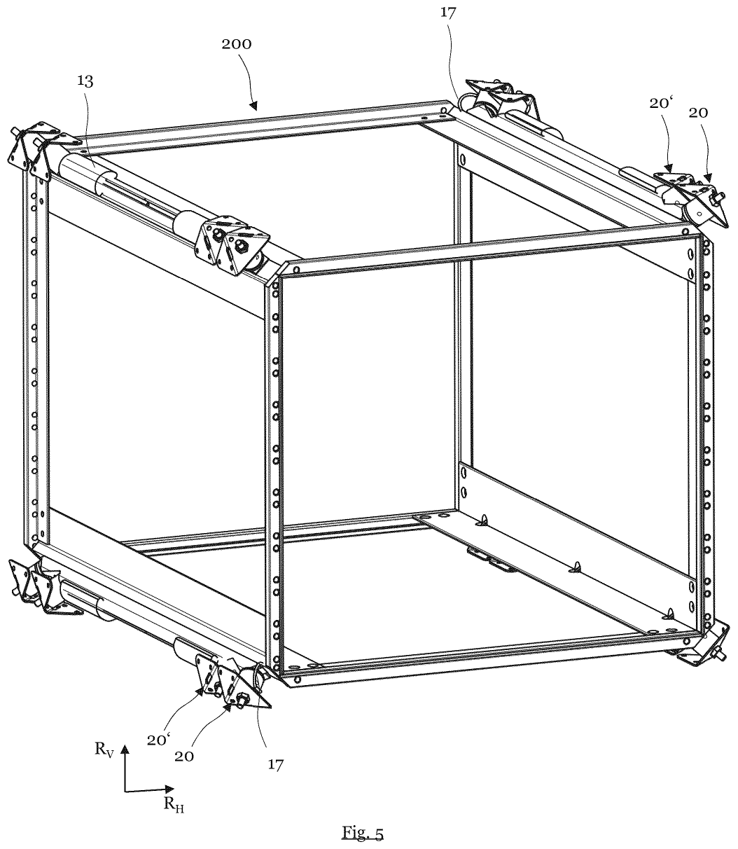

FIG. 5 shows a further embodiment of an oscillating frame 200 which has 16 bearing elements 20, 20′ instead of eight bearing elements 20, as shown in FIG. 4. In addition to the existing bearing elements 20, in this embodiment an additional bearing element 20′ is fastened to the oscillating frame in each case offset inward in the depth direction. Eight pairs of bearing elements 20, 20′ are thus fastened to the oscillating frame. The degree of damping can thus be increased or changed, in particular the combination of different degrees of hardness of the damper is possible.

Furthermore, an earthing cable 17 is shown in FIG. 5. The earthing cable 17 connects the oscillating frame in an electrically conductive manner to the housing connecting element 25 and thus to the housing body 100. This ensures an optimized earthing of the technical equipment items to be transported and ensures their safe and trouble-free function.

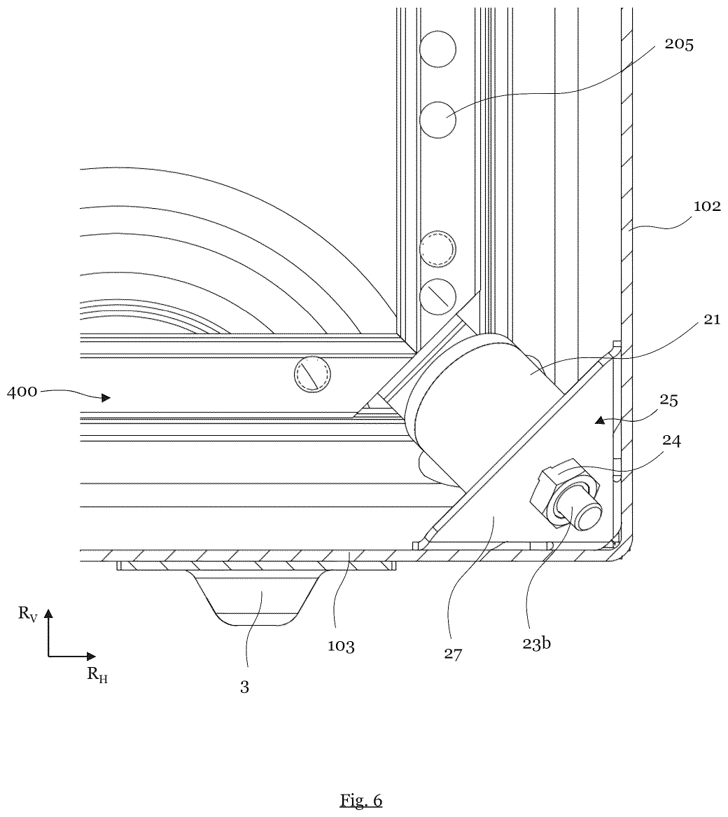

FIG. 6 shows a detailed view of the bearing element 20 in the installed state of the oscillating frame 400 in the housing body 100. It can be clearly seen that the housing connecting element 25 of the bearing element 20 is shaped in such a way that a surface 26 lies parallel to the side wall element 102 and a surface 28 (see FIG. 7) lies parallel to the lower wall element 103, and also that the central surface 27 is inclined at an angle of 45 degrees with respect to the two surfaces 26, 28. The buffer element 21 projects with the threaded pin 23b through the housing connecting element 25 through a concealed recess and is secured from the opposite side by means of the nut 24. As a result of the detachable connection of the buffer element 21 or of the entire bearing element 20, replacement of the bearing elements 20 in the support housing 1 is possible and the vibration or damping behavior of the oscillating frame 200 can be adapted as required.

FIG. 7 shows a detail view of the T-shaped adapter piece 70 in the installed state of the oscillating frames 200, 400 in the housing body 100. The adapter piece 70 has two sections 71 and 73 which stand perpendicularly with respect to one another. In the installed state, the first section 71 lies parallel to the side wall element 102 and is connected thereto. The second section 73 standing perpendicularly thereto projects horizontally or parallel to the upper and lower wall element 101, 103 into the interior of the housing body 100. In this case, the second section 73 forms the support for the bearing elements 20 of the upper and lower oscillating frame 200, 400. In particular, the surfaces 28 of the housing connecting elements 25 are fastened to the second section 73. The T-shaped adapter piece 70 forms the spatial separating element between two oscillating frames 200, 400 arranged one above the other.

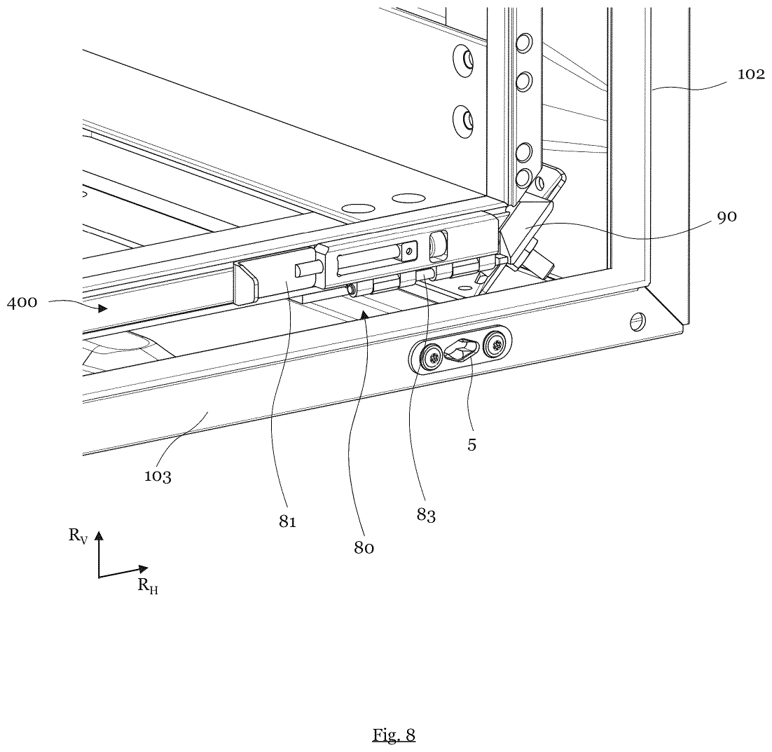

FIG. 8 shows an embodiment in which the oscillating frame 400 can be removed from the housing body 100 in a drawer-like manner. In particular, the locking mechanism 80 is shown in detail.

In the embodiment shown in FIG. 8, the oscillating frame 400 is not screwed directly to the threaded pins 23a of the buffer elements 21 of the bearing elements 20, but two bearing elements 20 which are adjacent in the depth direction are connected to a common guide rail 90 on the oscillating frame side. Four oscillatingly mounted guide rails 90, which are oriented parallel to the profile rods 51, 52, 53, 54 lying in the depth direction of the oscillating frame 400, are thus present per oscillating frame in the housing body 100. These guide rails 90 receive the oscillating frame 400 in a drawer-like manner at the corners thereof or profile rods 51, 52, 53, 54 in the depth direction, with the result that the oscillating frame 400 can be pushed into the housing body 100. In order to lock the oscillating frame 400 in the depth direction or to secure it against slipping, a locking mechanism 80 is attached to an end side of the housing body 100 for each oscillating frame. The latter can be unlocked by displacing the lever 81 toward the center of the housing body 100 and can be pivoted downward about the pivot axis 83. The oscillating frame 400 can be pulled out or pushed in in a drawer-like manner, wherein the bearing elements 20 always remain in the housing body 100.

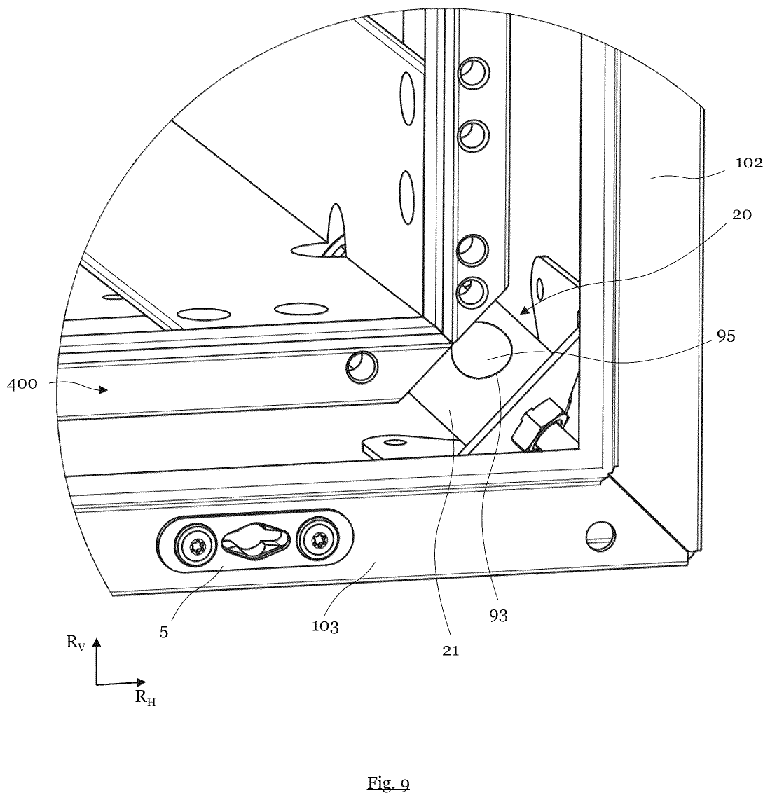

FIG. 9 illustrates an embodiment of a bearing element 20 with a changeable or adjustable degree of hardness or damping. The buffer element 21 is of cylindrical shape, with threaded pins 23a, 23b or threaded bores on the two end sides, in order to connect the buffer element 21 to the oscillating frame 400 or to the housing connecting element 25. A bore 93 is made laterally in the lateral surface of the cylindrical buffer element 21. The bore 93 can have a predetermined depth or be embodied as through-bores. The bore 93 forms an interface for receiving hardeners 95 adapted to the shape thereof. The hardener 95 is a pin which can be introduced into the bore 93 and fills the latter. By using hardener 95 of different hardness, made of material which is softer, equally hard or harder than that of the buffer element 21, in the bore 93, the degree of hardness or damping of the buffer element 21 and thus of the bearing element 20 can be changed and adjusted in a stepwise manner. Alternatively, no hardener 95 can also be inserted into the bore 93; in this case, the degree of hardness or damping of the buffer element 21 is the lowest.

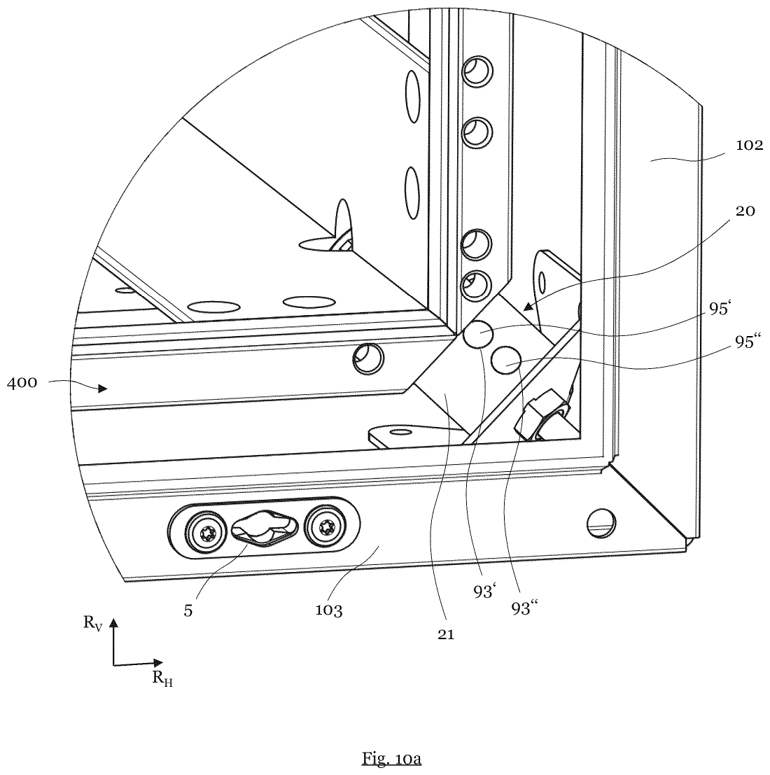

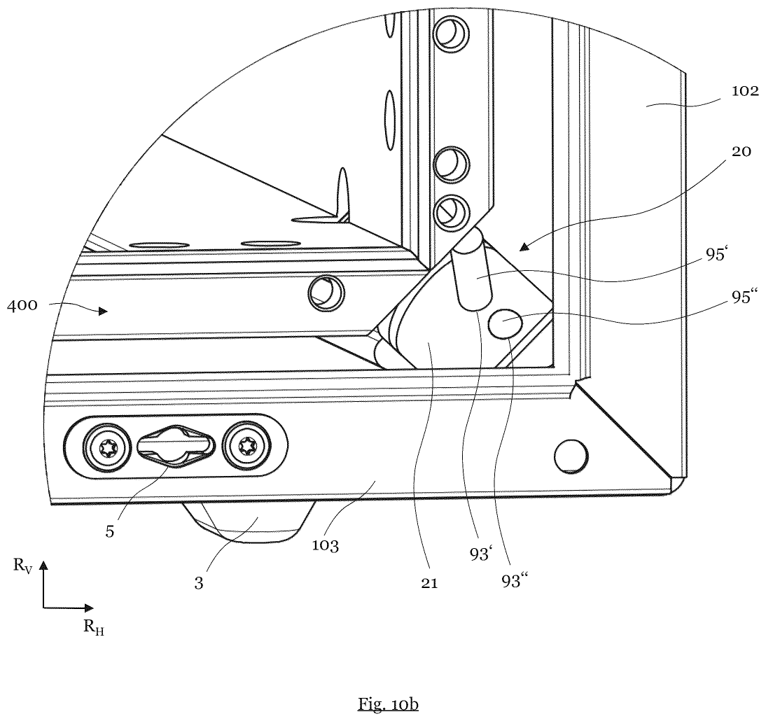

FIGS. 10a and 10b show an embodiment of the bearing element 20, in particular of the buffer element 21, in two operating states. In the embodiment shown, the degree of hardness or damping of the buffer element 21 can be adjusted or changed analogously to the embodiment in FIG. 9. However, two bores 93′ and 93″ are made laterally in the lateral surface of the cylindrical buffer element 21. As in the previous embodiment (FIG. 9), the bores 93′, 93″ can have a predetermined depth or be embodied as through-bores. It is not necessary for exactly two bores to be provided; alternatively, a plurality of bores can be provided in the buffer element 21. Analogously to the embodiment in FIG. 9, hardeners 95′, 95″ adapted to the shape of the bores 93′, 93″ are provided in the form of pins which are inserted into the bores 93′, 93″. FIG. 10 a shows an operating state of the bearing element 20, in which hardeners 95′, 95″ are inserted into the two bores 93′, 93″. FIG. 10 b shows an operating state of the bearing element 20, in which a hardener 95′ is pulled out of the bore 93′ and the second hardener 95″ is inserted into the second bore 93″. As a result of the use of two bores 93′, 93″, the number of combination possibilities of different hardeners 95′, 95″ and degrees of hardness or damping of the bearing element 20 achieved thereby is significantly increased compared with the embodiment from FIG. 9. In the embodiment according to FIG. 10 a and 10 b, there is of course the possibility of leaving one or both bores 93′, 93″ free, that is to say of inserting no hardener 95′, 95″ and, in the first case, of inserting a hardener 95′, 95″ only into one of the bores 93′, 93″.

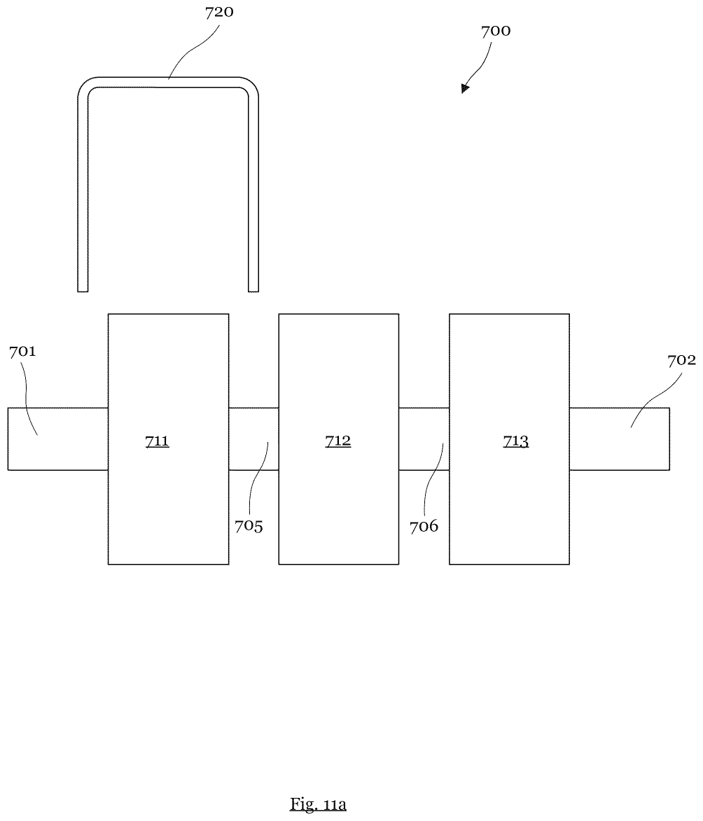

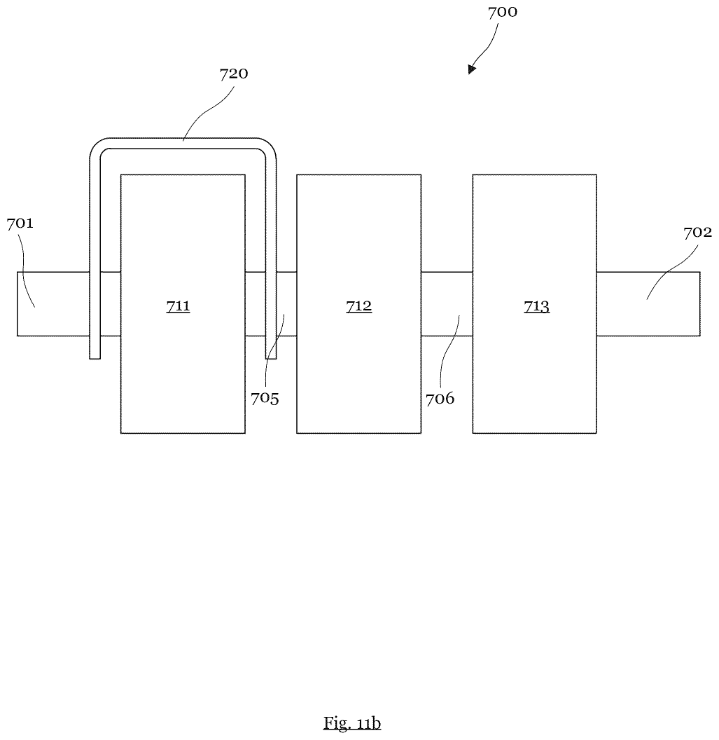

A further embodiment of an adjustable or changeable buffer element 700 is illustrated as a basic illustration in FIG. 11 a. The buffer element 700 has two connection elements 701, 702, via which the buffer element 700 can be connected, for example, to oscillating frame 200 and housing connecting element 25. The connection elements 701, 702 can correspond, for example, to the threaded pins 23a, 23b of the previously described buffer element 21. In the embodiment shown, three buffers 711, 712 and 713 are connected in series between the two connection elements 701, 702 and are rigidly connected to one another via two connecting elements 705, 706. A series connection of three individual buffers 711, 712, 713 thus results overall for the buffer element 700. The individual buffers 711, 712, 713 can have either the same or different degrees of hardness or damping. As a result, a plurality of different degrees of damping can be adjusted by combining buffers of different hardness. The embodiment of the buffer element 700 is not restricted to exactly three buffers 711, 712, 713, but can also be embodied with one, two or more than three buffers which can be combined with one another in different hardnesses.

FIG. 11 a furthermore shows a bridging clip 720 in a passive state. The bridging clip 720 has, by way of example, a U-shaped cross section, but can also be of a different shape. The bridging clip 720 is configured in such a way, in an active state, to bridge one of the buffers 711, 712 or 713, that is to say to deactivate it. FIG. 11 b shows the bridging clip 720 in an active state. In the passive state of the bridging clip (FIG. 11 a), the force flow through the buffer element 700 takes place from the connection element 701 via each of the buffers 711, 712, 713 and the two connecting elements 705, 706 to the connection element 702. Each of the three buffers 711, 712, 713 thus contributes actively to the vibration damping. In the active state of the bridging clip 720 (FIG. 11 b), the force flow in the buffer element 700 takes place from the connection element 701 via the rigid bridging clip 720 (instead of the buffer 711) to the connecting element 705 and via the buffers 712 and 713 and the connecting element 706 to the connection element 702. The buffer 711 is thus deactivated in the active state of the bridging clip 720 and does not contribute to the vibration damping. It goes without saying that the bridging clip 720 can alternatively also be used in such a way that it bridges one of the two other buffers 712 or 713. Alternatively, a plurality of bridging clips 720 can also be used and thus, for example, a rigid connection between the connection elements 701, 702 can also be produced. By this selective bridging of individual buffers in the buffer element 700 by means of the bridging clip 720, the degree of hardness or damping of the buffer element 700 can be adjusted or changed easily and precisely.

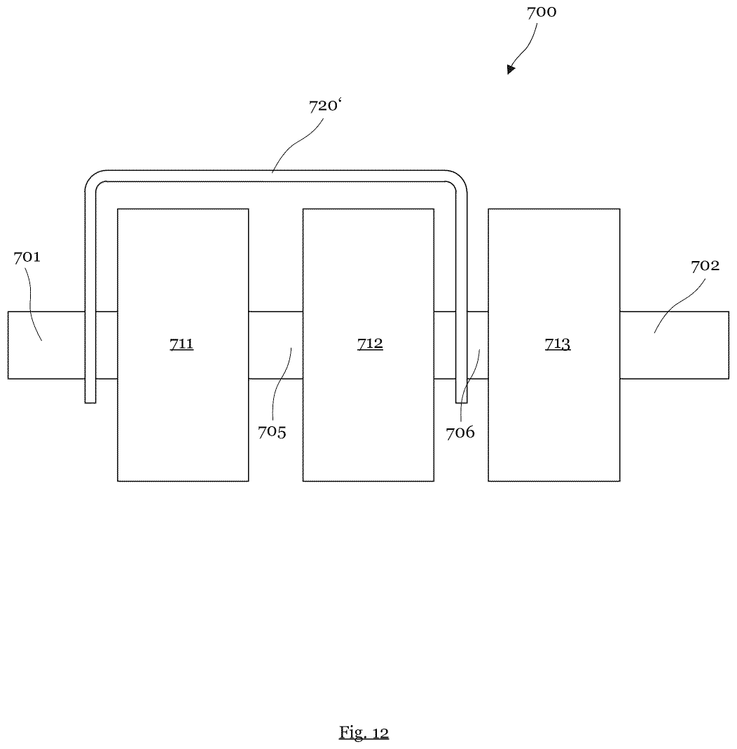

FIG. 12 shows an alternative embodiment of the bridging clip 720 shown in FIGS. 11a and 11 b. The bridging clip 720′ from FIG. 12 is configured in such a way that it bridges two buffers 711, 712 of the buffer element 700 simultaneously. It goes without saying that the bridging clip 720 'can also be used in order to bridge the buffers 712 and 713.

The features disclosed in the above description, the figures and the claims can be of importance for the implementation of the invention in the various embodiments both individually and in any combination.

### REFERENCE SIGN LIST

1 Support housing
3 Foot
5 Closure recess
9 Carrying handle
11 countersinking
13 Stop damper
15 Closure cover
17 Earthing cable
20 bearing element
20′ Additional Bearing Element
21 Buffer element
23 a, 23 b threaded pin
24 nut
25 Housing connecting element
26, 28 Outer surface of the housing connecting element
27 Central surface of the housing connecting element
40, 40′ End side of the oscillating frame
41, 42, 43, 44 Profile rods of the end side
51, 52, 53, 54 Profile rods
61 Stiffening element
63 attached profile rods
65 Bearing mounting surface
70 adapter piece
70a, 70b Adapter Piece Pair
71 First section of the adapter piece
73 Second section of the adapter piece
80 locking mechanism
81 lever
83 Pivot axis
90 Guide rail
93, 93′, 93″ Bore
95, 95′, 95″ Hardener
100 Housing body
101 Upper wall element
102 Lateral wall element
103 Lower wall element
104 Lateral wall element
200 Upper oscillating frame
205 Fastening hole of the upper oscillating frame
300 Middle oscillating frame
400 Lower oscillating frame
405 Fastening hole of the lower oscillating frame
700 changeable buffer element
701, 702 Connection element
705, 706 Connecting element
711, 712, 713 Buffer
720, 720′ Bridging clip
B Nominal width of the support housing
T Nominal depth
H Nominal height
B_{S} Width of the oscillating frame
T_{S} Depth of the oscillating frame
H_{S} Height of the oscillating frame
R_{H} Horizontal direction of the support housing
R_{V} Vertical direction of the support housing

What is claimed is:

1. A support housing for receiving technical equipment items, comprising a housing body, in particular according to the 19″ grid dimension according to DIN EN 60297-3-100 or EIA-310-E or according to the half 19″ grid dimension, and at least two oscillating frames mounted independently of one another in the housing body for receiving in each case at least one technical equipment item, wherein at least one oscillating frame is mounted elastically with respect to the housing body.

2. The support housing according to claim 1, wherein the at least one further oscillating frame is mounted in the housing body in such a way that its relative oscillating ability with respect to the housing body as a result of external forces acting on the housing body is lower than that of the at least one other oscillating frame.

3. The support housing according to claim 1, wherein the at least one further oscillating frame is rigidly connected to the housing body or is mounted elastically with respect to the housing body and/or is mounted in the housing body in particular in a drawer-like removable manner, wherein in particular the at least one oscillating frame mounted elastically with respect to the housing body is mounted in the housing body in particular in a drawer-like removable manner.

4. The support housing according to claim 1, wherein the elastic mounting comprises at least one buffer made of elastic material, such as rubber in particular with a hardness in the range from 40 to 100 Shore A, a wire cable damper or a functionally equivalent damping element, wherein in particular two buffer or wire cable damper elements are provided per corner of the oscillating frame.

5. The support housing according to claim 1, wherein a relative oscillating ability of the at least one elastically mounted oscillating frame with respect to the housing body is adjustable, wherein in particular the relative oscillating ability is adjustable by an adaptation of the hardness of the elastic mounting or by selective de-/activation of interacting elastic mounting elements.

6. The support housing according to claim 1, wherein the elastic mounting comprises at least one elastic buffer which comprises an interface, such as a receptacle, for connecting to a hardener in order to adjust the oscillating ability of the elastic mounting in a stepwise manner.

7. The support housing according to claim 1, wherein the elastic mounting is formed by a series connection of at least two in particular identically formed elastic buffer elements and at least one de-and activatable bridging clamp is provided which is configured to adjust the oscillating ability of the elastic mounting by adding or bridging individual buffer elements.

8. The support housing according to claim 1, further comprising an adapter piece which is in particular T-shaped in cross section, which is fixedly attached to the housing body and is formed for supporting at least two oscillating frames arranged one above the other in a height unit direction.

9. The support housing, in particular according to claim 1, for receiving technical equipment items, comprising a housing body, in particular according to the 19″ grid dimension according to DIN EN 60297-3-100 or EIA-310-E or according to the half 19″ grid dimension, at least one oscillating frame for receiving in each case at least one technical equipment item and a mounting for in particular elastically supporting the oscillating frame on the housing body, which is configured adjustably in such a way that a relative oscillating ability of the oscillating frame with respect to the housing body is in particular continuously adjustable.

10. The support housing according to claim 9, further comprising a sensor system which is configured to detect the weight and/or an acceleration acting on the support housing and/or a vibration acting on the support housing, and a controller which is configured to adjust the relative oscillating ability depending on the sensor system.

11. The support housing according to claim 9, further comprising a database on which empirical values for the weight and/or an acceleration acting on the support housing and/or a vibration acting on the support housing are stored, and a controller which is configured to adjust the relative oscillating ability depending on the empirical values of the database.

12. A modular system for a support housing configured in particular according claim 1 for receiving technical equipment items, comprising a plurality of housing bodies which differ with respect to a width (B) according to the 19″ grid dimension according to DIN EN 60297-3-100 or EIA-310-E or according to the half 19″ grid dimension, a height unit dimension (H) and/or a nominal depth (T), a plurality of oscillating frames adapted in each case to an overall dimension of a housing body for receiving in each case at least one technical equipment item and a plurality of mountings for supporting the oscillating frames in the housing body, which differ from one another with respect to a relative elastic oscillating ability of the oscillating frame with respect to the housing body, a fastening interface for connecting to the housing body and/or the oscillating frame, and/or the installation space requirement, wherein for forming a support housing a housing body, at least one oscillating frame and at least one mounting are combined.

13. The modular system according to claim 12, wherein a plurality of pre-assembly units are provided by in each case one oscillating frame and at least one mounting being pre-assembled.
